(19) United States
(12) Patent Application Publication
(10) Pub. No.: US 2009/0078571 A1
(43) Pub. Date: Mar. 26, 2009

(54) MAGNET ASSEMBLY CAPABLE OF GENERATING MAGNETIC FIELD HAVING DIRECTION THAT IS UNIFORM AND CAN BE CHANGED AND SPUTTERING APPARATUS USING THE SAME

(75) Inventors: Einstein Noel Abarra, Hachioji-shi (JP); Tetsuya Endo, Kokubunji-shi (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/145,456

(22) Filed: Jun. 24, 2008

Related U.S. Application Data
(63) Continuation of application No. PCT/JP2007/068627, filed on Sep. 26, 2007.

(51) Int. Cl. H01F 7/02; C23C 14/35

(52) U.S. Cl. 204/298.16; 335/306

(57) ABSTRACT

The magnet assembly includes one rotatable dipole magnet subassembly, which is formed from a permanent magnet and a magnetically permeable convex end portion coupled to each of both ends of the permanent magnet, and at least two magnetically permeable flux guide subassemblies, which are configured so as to be magnetically coupled to the dipole magnet subassembly. The flux guide subassembly has a concave end portion that fits into the convex end portion. The flux guide assemblies guide a flux from the dipole magnet subassembly and generate a flux outside. The condition of fitting into the flux guide subassemblies is reversed by rotating the dipole magnet subassembly, whereby it is possible to easily reverse the direction of a magnetic field generated outside.

### TECHNICAL FIELD

The present invention relates to a magnet assembly capable of generating a magnetic field with a uniform and variable direction and a sputtering apparatus that forms a thin film on a substrate using the magnet assembly. More specifically, the present invention relates to a magnet assembly that can change the direction of a magnetic field generated by permanent magnets in a rotatable dipole magnet subassembly, and a sputtering apparatus for forming a thin film of a soft magnetic material having a magnetic anisotropy set in the same direction over a substrate using the magnet assembly.

### BACKGROUND ART

A soft magnetic layer having a high-moment magnetic anisotropy is required for write heads for magnetic recording storage and magnetoresistive random access memory (MRAM). Also, for example, in the field of magnetoresistive sensors and the like, it is necessary to perform annealing treatment in a magnetic field with a uniform direction in order to obtain a magnetic anisotropy with uniform anisotropy directions over the entire substrate. Such annealing treatment, however, may sometimes cause diffusion in a metal film, changes in crystal structure, and damage a resist film with a low allowable temperature limit. For this reason, a method of sputtering for forming a soft magnetic layer in the presence of a magnetic field of uniform direction is preferable.

Arrangements capable of being used to form such a soft magnetic layer on a substrate have hitherto been proposed. For example, U.S. Pat. No. 5,519,373 (Patent Document 1) discloses an arrangement in which a plurality of columnar permanent magnets are disposed along the circumference of a hollow, cylindrical nonmagnetic fixing tool. Each of the permanent magnets is magnetized in different directions and a magnetic field of one prescribed direction as a whole is formed. A substrate is disposed in the interior of the hollow, cylindrical fixing tool and a soft magnetic material is sputtered on the substrate, whereby a film of a magnetic anisotropy guided in a desired direction can be formed.

On the other hand, techniques that use electromagnets in place of permanent magnets have also been proposed. U.S. Pat. No. 6,475,359 (Patent Document 2) discloses sputtering that is performed, with a magnetic field of one desired direction applied, by disposing a planar electromagnet under a substrate supporting bed. U.S. Pat. No. 6,790,482 (Patent Document 3) proposes an arrangement consisting of at least three electromagnets. The dipole axis of each of the electromagnets is parallel to a plane, and these electromagnets are disposed in such a manner as to form a closed surface as viewed from a direction perpendicular to the plane. And by providing this magnetic arrangement under a substrate supporting bed installed within a vacuum chamber, it is possible to form a magnetic layer having a desired anisotropic direction on the substrate.

Patent Document 1: U.S. Pat. No. 5,519,373
Patent Document 2: U.S. Pat. No. 6,475,359
Patent Document 3: U.S. Pat. No. 6,790,482

In actually performing sputtering onto a substrate, it is important to control the intensity and direction of the magnetic field to reduce the effect of the magnetic field applied to the substrate on the trajectory of sputtered particles and to reduce interference with the leakage magnetic field from an opposed cathode magnet. Particularly, it is preferred that the direction of a magnetic field be reversed by 180 degrees during sputtering. Therefore, it is necessary that after the sputtering process is performed for a specified time, with a unidirectional magnetic field applied to the substrate, the direction of the magnetic field be reversed, and that the sputtering process be performed again, with a unidirectional magnetic field of a reversed direction applied to the substrate. That is, even when a magnetic field applied to the substrate has an effect on the trajectory of sputtered particles and nonuniformity of film thickness distribution is caused by interference with a leakage magnetic field from the opposed cathode magnet, it is possible to cancel out the thickness nonuniformity by reversing the application direction of the magnetic field.

The arrangement in which permanent magnets are used as in Patent Document 1 has the advantage that unlike electromagnets, it is unnecessary to supply large electric power. However, because the direction of a magnetic field applied to the substrate is fixed, it is necessary to reverse the direction of the magnets with respect to the substrate in order to reverse the direction of the magnetic field. Therefore, a rotary mechanism for this purpose is necessary and this makes the sputtering apparatus complex, resulting in a cost increase.

On the other hand, in the case of Patent Document 2 and Patent Document 3 where electromagnets are used, it is unnecessary to mechanically rotate the sputtering apparatus and it is possible to easily reverse the direction of a magnetic field by changing the direction of a current given to the electromagnets. However, for this purpose, it is necessary to cause a large current to flow through the electromagnets, posing the problem that the temperature within the vacuum chamber rises. Therefore, it is necessary to provide a cooling mechanism for preventing this temperature rise, and the cost of the sputtering apparatus increases.

Furthermore, these conventional arrangements were intended for generating a uniform magnetic field in a relatively small region. However, wafers used in a write head for magnetic recording medium and MRAMs have a diameter of at least 5 inches (12.7 cm) and sometimes as large as 12 inches (30.48 cm).

An object of the present invention is to realize a low-cost magnet assembly that generates a unidirectional magnetic field all over a relatively large region, can change the direction, and does not require a mechanism for rotating the whole arrangement or a cooling mechanism.

Also, another object of the present invention is to realize a sputtering apparatus that can form a thin film having a magnetic anisotropy guided in the same direction all over the whole substrate by using such a magnet assembly.

### SUMMARY OF THE INVENTION

To achieve the above-described objects, the magnet assembly of the present invention comprises at least one rotatable dipole magnet subassembly, which includes a permanent magnet and a magnetically permeable convex end portion coupled to each of both pole ends of the permanent magnet, and at least two magnetically permeable flux guide subassemblies, which are configured to be magnetically coupled to the dipole magnet subassembly. Each of the flux guide subassemblies has a concave end portion that fits into the convex end portion of the dipole magnet subassembly. When one of the convex end portions of the dipole magnet subassembly fits into the concave end portion of one of the flux guide subassemblies, the other convex end portion fits into the concave end portion of other flux guide subassembly and the flux guide assemblies guide a magnetic flux from the dipole magnet subassembly and generate a magnetic field outside. The magnet assembly of the present invention has means for rotating the dipole magnet subassembly, and the condition of fitting into the at least two flux guide subassemblies (and the configuration of the dipole magnet subassembly) is reversed by rotating the dipole magnet subassembly, whereby it is possible to easily reverse the direction of the magnetic field generated outside.

The magnet assembly of the present invention may be configured to comprise at least two dipole magnet subassemblies and at least three flux guide subassemblies. In this case, the at least two dipole magnet assemblies are preferably disposed in tandem and at least one flux guide subassembly is disposed between the two dipole magnet assemblies.

Each of the flux guide subassemblies may be configured to comprise a first arm having the concave end portion and a second arm that extends perpendicularly to the first arm from an end portion opposite to the concave end portion of the first arm. In this case, a flux from the dipole magnet subassembly is guided by the first and second arms, whereby a magnetic field is generated outside an end of the second arm.

In the magnet assembly of the present invention, the permanent magnet may comprise a plurality of magnets having the same length. The plurality of magnets may have different magnetic forces, and a magnet of a stronger magnetic force may be disposed nearer to the end portion of the permanent magnet.

The flux guide subassemblies may be configured to have a thickness that is not uniform. A sputtering apparatus can be formed by using a magnet assembly as described above. The sputtering apparatus of the present invention comprises a vacuum chamber, a substrate holder disposed within the vacuum chamber, an electrode or a source that holds a target material, and a magnet assembly having the above-described features.

The sputtering apparatus may be configured to comprise two magnet assemblies that are disposed in positions opposed to each other, with the substrate holder interposed therebetween. When the magnet assembly has a first arm and a second arm as described above, the sputtering apparatus may be configured to further comprise a third arm that connects each of the second arms of the opposed flux guide subassemblies, whereby it is possible to improve the uniformity of the direction of a magnetic field applied to the substrate surface.

The magnet assembly may be disposed either outside or inside the vacuum chamber. The electrode that holds the target material may be configured to further comprise a cathode electrode that rotates in synchronization with the rotation of the dipole magnet subassembly.

When the diameter of the substrate is denoted by D and the length L, width W and height H of the magnet assembly are represented by L=xD, W=yD and H=zD, respectively, the size of the magnet assembly applied to the sputtering apparatus of the present invention preferably meets: 1.5≦x≦2, 1.5≦y≦2 and 0.5≦z≦1.

The magnet assembly of the present invention enables a magnetic field of a uniform direction to be formed on a substrate surface of 5 inches to 12 inches in diameter or of larger sizes. Because of the feature that the direction of a magnetic field is reversed by rotating only the dipole magnet subassembly, a mechanism for rotating the whole assembly becomes unnecessary. Also, because it is unnecessary to use an electromagnet, it is unnecessary to cause a large current to flow and a cooling mechanism is unnecessary. Therefore, the construction of the assembly can be simplified and the cost can be reduced.

By using the sputtering apparatus of the present invention provided with such a magnet assembly, it becomes possible to form a thin film having magnetic anisotropy with substantially uniform direction throughout the whole substrate.

### BRIEF DESCRIPTION OF THE DRAWING

FIG. 1 is a diagram showing the construction of a magnet assembly related to an embodiment of the present invention;

FIG. 2 is a diagram showing the construction of a magnet assembly in which the thickness of a flux guide subassembly is not uniform;

FIG. 3 is a diagram showing the construction of a sputtering apparatus related to an embodiment of the present invention;

FIG. 4 is a diagram showing the construction of a magnet assembly related to another embodiment of the present invention and of a sputtering apparatus using this magnet assembly;

FIG. 5 is a diagram showing the construction of a magnet assembly related to another embodiment of the present invention and of a sputtering apparatus using this magnet assembly;

FIG. 6 is a perspective view of the construction of FIG. 4;

FIG. 7 is diagrams showing calculation results of variations in the inclination of the direction of a magnetic field and of the intensity of a magnetic field under the conditions of FIG. 5;

FIG. 8 is a perspective view of a sputtering apparatus that further includes a cathode magnet;

FIG. 9 is a diagram showing the relationship between the rotation of a dipole magnet subassembly and the rotation of a cathode magnet;

FIG. 10 is a diagram showing a concrete example of construction of a sputtering apparatus of the present invention; and

FIG. 11 is a diagram showing another example of construction of a sputtering apparatus of the present invention.

### LIST OF SYMBOLS

1 Magnet assembly
2 Rotary shaft
3 Line of magnetic force
4 Sputtering apparatus
5 Magnet assembly
6 Sputtering apparatus
7 Magnet assembly
8, 8a, 8b Sputtering apparatus
10 Dipole magnet subassembly
11 Permanent magnet
12, 13 Magnetically permeable end portion
20, 21, 26 Flux guide subassembly
21a, 21b, 21c Part of flux guide subassembly
22, 23 Concave end surface
24, 25 End surface on the opposite side
30, 31 Flux guide subassembly
30a, 31a First arm
30b, 31b Second arm
30c, 31c Third arm
40 Substrate holder
50 Substrate
60 Cathode magnet
70 Vacuum chamber
80 Electrode
90, 110 Target
100 Gas introduction port
120 Shutter

### DETAILED DESCRIPTION OF EMBODIMENTS

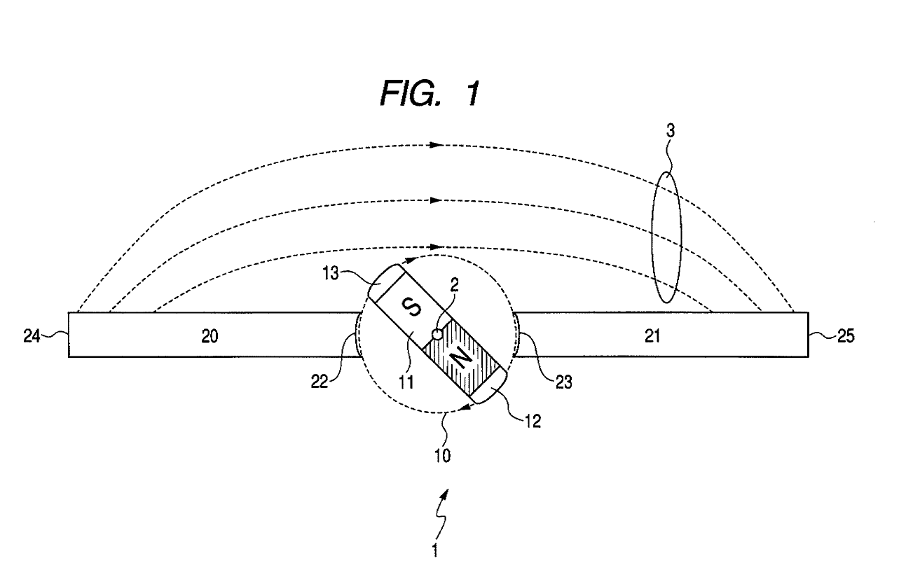

FIG. 1 is a diagram showing the construction of a magnet assembly 1 related to an embodiment of the present invention. The magnet assembly 1 comprises a dipole magnet subassembly (a partially assembled part) 10 capable of rotating around a shaft 2 perpendicular to the sheet surface and at least two flux guide subassemblies 20 and 21.

The dipole magnet subassembly 10 comprises at least one permanent magnet 11 and two magnetically permeable end portions 12 and 13, which are provided for each permanent magnet. The magnetically permeable end portions 12 and 13 have convex end portions. The permanent magnet 11 preferably has the shape of a bar or the shape of a square, and may be formed from a plurality of magnets having the same length. The plurality of magnets may include magnets having different magnetic forces. In this case, a magnet of a stronger magnetic force can be disposed nearer to the end portion of the permanent magnet 11 in order to improve uniformity of magnetic field direction.

On the other hand, in the flux guide subassemblies 20 and 21, the end surfaces 22 and 23 on the side nearer to the dipole magnet subassembly 10 are concave. The flux guide subassemblies 20 and 21 are formed from a ferritic stainless steel (SUS) 430, SUS410, a rolled steel for general structure (SS) 400, an electromagnetic soft iron (SUY) or magnetically permeable materials of alloys of iron and copper and the like.

When the dipole magnet subassembly 10 is rotated around the shaft 2 and disposed in a direction in which the longitudinal direction thereof coincides with the longitudinal direction of the flux guide subassemblies 20 and 21 (the horizontal direction of the figure), the dipole magnet subassembly 10 and the flux guide subassemblies 20 and 21 are caused to mate with each other via the convex end surfaces of the end portions 12 and 13 and the concave end surfaces 22 and 23. When the end portion 12 of the permanent magnet 11 on the N pole side is caused to mate with the flux guide subassembly 20, a magnetic flux generated from the N pole of the permanent magnet 11 is guided in the flux guide assembly 20 via the end portion 12 and the end surface 22 and emanates from near the end surface 24 on the opposite side to the outside. This magnetic flux is guided again in the flux guide subassembly 21 from near the end surface 25 of the flux guide subassembly on the opposite side and reaches the end portion 13 of the permanent magnet 11 on the S pole side. A plurality of arrows with dotted lines 3 in FIG. 1 indicate the direction of magnetic field lines generated outside the magnet assembly 1.

Furthermore, a magnetic field of a direction opposite to the direction of the illustrated lines of magnetic force 3 is easily formed by simply rotating the dipole magnet subassembly 10 around the rotary shaft 2 and causing the end portion 12 to mate with the flux guide subassembly 21. The magnet assembly 1 of the present invention can generate a reversible magnetic field of a uniform direction. Moreover, by using the flux guide subassemblies 20 and 21, it is possible to generate such a magnetic filed over a relatively large region.

Incidentally, the rotary shaft 2 of the dipole magnet subassembly 10 does not always have to be perpendicular to the sheet surface in FIG. 1, but may be parallel to the sheet surface, for example. What is needed is that a smooth shift be capable of being made from a condition in which one of the end portions 12 and 13 of the dipole magnet subassembly 10 is caused to mate with the flux assembly 20 to a condition in which the other end portion is caused to mate with the flux guide assembly 20.

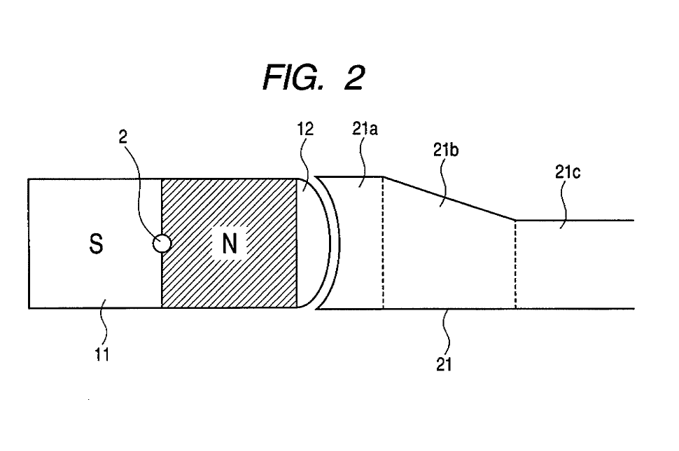

The flux guide assemblies 20 and 21 may have a thickness that is not uniform. An example of such a construction is shown in FIG. 2. In FIG. 2, the flux guide assembly 21 is formed from a portion 21a having a uniform thickness that is almost the same as that of the permanent magnet 11, a portion 21c that is thinner than the permanent magnet 11 and has a uniform thickness, and a portion 21b that is interposed between these portions 21a and 21c and has a thickness that becomes smaller with increasing distance from the permanent magnet.

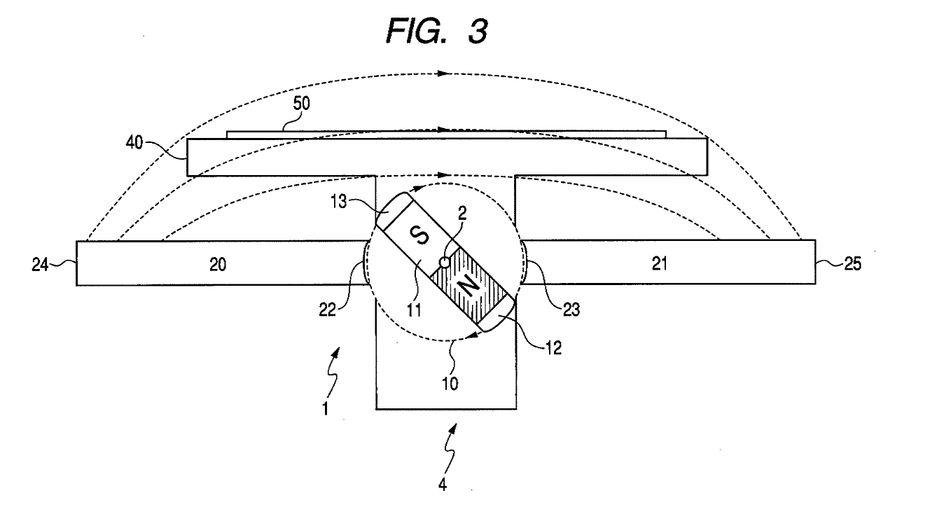

FIG. 3 shows the construction of the sputtering apparatus 4 related to an embodiment of the present invention, which is formed by using the magnet assembly 1. The sputtering apparatus 4 comprises the magnet assembly 1 shown in FIG. 1 and a substrate holder 40 on which a substrate 50 is to be placed. The rotary shaft 2 of the dipole magnet subassembly 10 is attached to, for example, a supporting column of the substrate holder 40. Usually, the substrate holder 40 is disposed within a vacuum chamber. The magnet assembly 1 attached to the substrate holder 40 is configured to be disposed inside or outside the vacuum chamber. Within this vacuum chamber, an electrode or a source that supports a soft magnetic target material is further provided above the substrate 50, and it is possible to form a soft magnetic layer on the substrate 50 by a sputtering process or the like. As already described, a magnetic field of a uniform direction capable of being changed can be applied by the magnet assembly 1 to the surface of the substrate 50, and it is possible to form a soft magnetic thin film having a magnetic anisotropy that is oriented in substantially the same direction throughout the whole substrate 50. After the sputtering processing is performed for a given time, the direction of a magnetic field on the surface of the substrate 50 is reversed by reversing the direction of the dipole magnet subassembly 10 and the sputtering process is performed again for a given time. As a result of this, it is possible to reduce the effect of an applied magnetic force on the trajectory of sputtered particles.

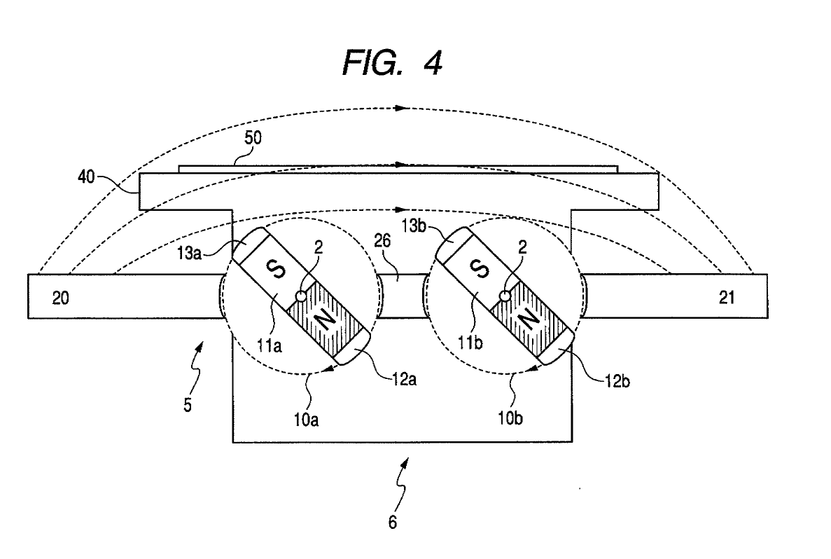

FIG. 4 shows the construction of a magnet assembly 5 related to another embodiment of the present invention and of a sputtering apparatus 6 using this magnet assembly. At least two dipole magnet subassemblies 10a and 10b are used to intensify a magnet field formed on the surface of a substrate 50. In FIG. 4, the two dipole magnet subassemblies 10a and 10b are disposed in tandem. In addition to the flux guide subassemblies 20 and 21, another flux guide subassembly 26 is further disposed between the two dipole magnet subassemblies. The plurality of dipole magnet subassemblies are preferably rotated in a synchronous manner in order to generate a stronger magnetic field. For example, when an end portion 12a of the dipole magnet subassembly 10a on the N pole side comes into contact with the flux guide subassembly 20, an end portion 12b of the dipole magnet subassembly 10b on the N pole side comes into contact with the flux guide subassembly 26. The operation of the sputtering apparatus 6 is the same as with the case of FIG. 3. After the sputtering processing is performed for a given time, the direction of a magnetic field on the surface of the substrate 50 is reversed by reversing the direction of the dipole magnet subassemblies 10a and 10b and the sputtering process is performed again for a given time.

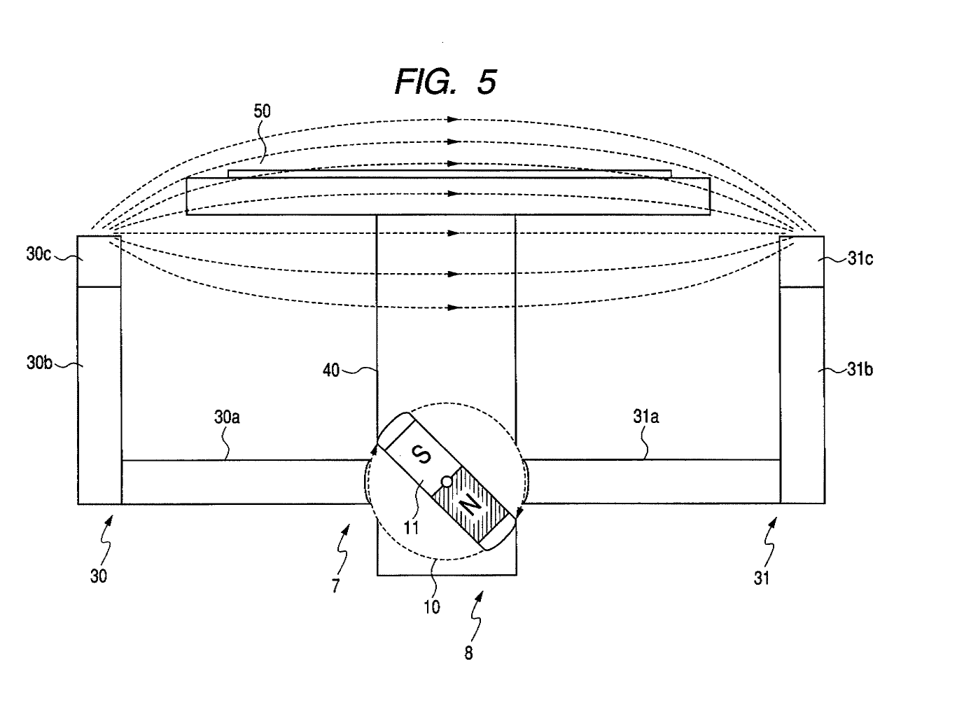

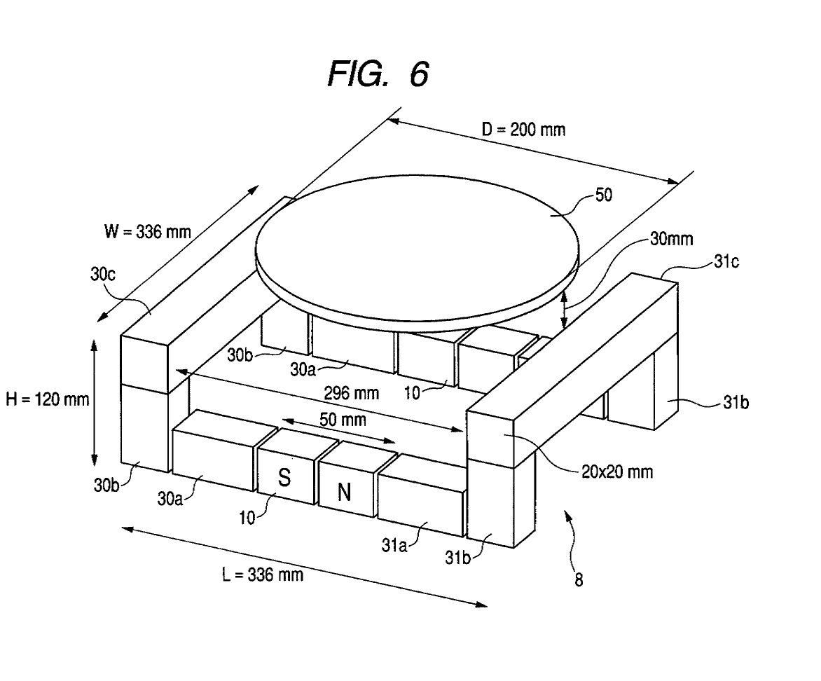

FIG. 5 shows the construction of a magnet assembly 7 related to a further embodiment of the present invention and of a sputtering apparatus 8 using this magnet assembly. FIG. 6 is a perspective view of FIG. 5. In FIG. 6, a substrate holder 40 is omitted so that the construction of the magnet assembly 7 can be more clearly understood. Although in FIG. 5 the single dipole magnet subassembly 10 is used, a plurality of dipole magnet subassemblies may be disposed tandem as in FIG. 4.

In the magnet assembly 8 of this embodiment, flux guide subassemblies 30 and 31 comprise first arms 30a and 31a that extend horizontally and second arms 30b and 31b that extend perpendicularly from end portions in the first arms 30a and 31a on the side far from the dipole magnet subassembly 10. Furthermore, when such a magnet assembly 8 is used in quantities of two in parallel as shown in FIG. 6, third arms 30c and 31c, which are configured to extend from the second arms 30b and 31b and bridge these two magnet assemblies are provided.

The first to third arms are formed from a ferritic stainless steel (SUS) 430, SUS410, a rolled steel for general structure (SS) 400, an electromagnetic soft iron (SUY) or magnetically permeable materials of alloys of iron and copper and the like. Although in FIGS. 5 and 6 these first to third arms are shown as separate members, they may be integrally formed.

In the condition of FIG. 6, a magnetic flux generated from the N pole of the dipole magnet subassembly 10 is guided in the first arm 31a and further guided in the second arm 31b that extends perpendicularly from the first arm 31a. Therefore, compared to the embodiment of FIGS. 1 to 3 in which the flux guide subassemblies 20 and 21 having a horizontal construction are used, it is possible to dispose the dipole magnet subassembly 10 of this embodiment in a position spaced farther from the stage of a substrate holder 40 and a substrate 50 placed thereon. Owing to this construction, it is possible to reduce the effect of a leakage magnetic field on the magnetic field on the surface of the substrate 50, the leakage magnetic field may arise from the permanent magnet 11 to the outside without being guided in the flux guide subassemblies 30 and 31.

FIG. 6 shows an example of the size of each component of the sputtering apparatus 8 when the diameter D of a substrate, which is the object of sputtering, is 200 mm. The length L from the end of the second arm 30b to the end of the second arm 31b and the width W of the third arms 30c and 31c are 336 mm. The height H from the bottom end of the second arms 30b and 31b to the top end of the third arms 30c and 31c is 120 mm. The length of the dipole magnet subassembly 10 is 50 mm, the distance from the end of the first arm 30a to the end of the first arm 31a is 296 mm, and the size of the section of the third arms 30c and 31c is 20 mm×20 mm. Incidentally, the material for these arms was SS400.

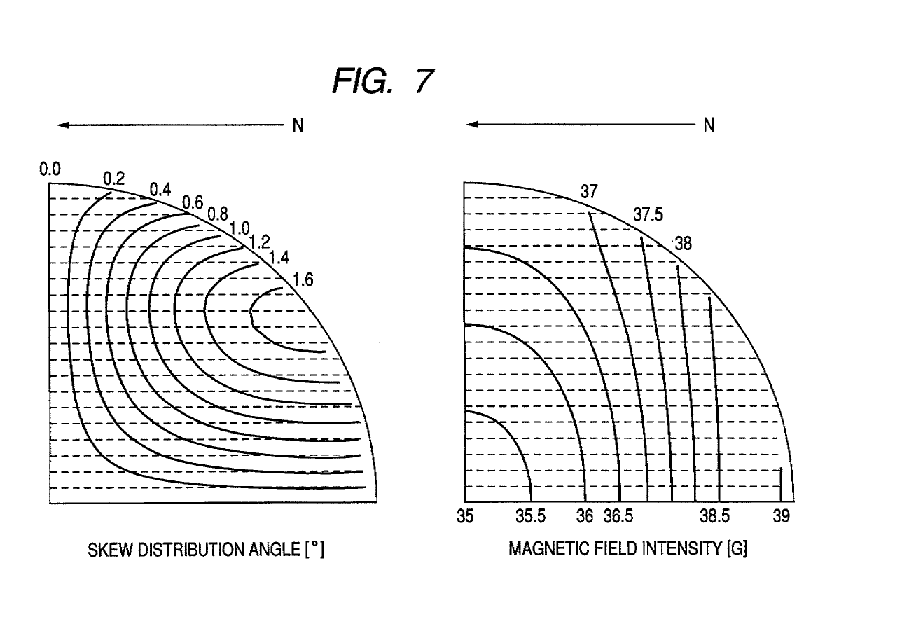

The direction and intensity of a magnetic field formed on the surface of the substrate 50 was calculated under these conditions. As a precondition for the calculation, Neodymium-Iron-Boron (NdFeB) was selected as the material for the permanent magnet 11, and a maximum magnetic energy product was assumed to be 48 MGOe. It is assumed that the N pole side of the dipole magnet subassembly 10 comes into contact with the first arm 31a, and hence the magnetic field is generated in a direction from the third arm 31c to the third arm 30c. The skew distribution angle and magnetic field intensity calculated for an upper right ¼ portion of the substrate 50 are shown in FIG. 7. The arrows in FIG. 7 indicate the direction of the magnetic field on the substrate 50.

As shown in the left-hand diagram of FIG. 7, variations in the direction of a magnetic field have very small values of less than 2° (1.69° at the maximum). Furthermore, as shown in the right-hand diagram of FIG. 7, magnetic fields in the range of 35 G to 39 G can be generated. It was shown from the calculation result that according to the present invention, a magnetic field of a substantially uniform direction could be generated on the substrate.

Furthermore, calculations were made to specify preferable ranges of the values of L, W and H in FIG. 6. It became apparent that when the diameter of the substrate was denoted by D and L=xD, W=yD and H=zD, the following conditions were necessary: 1.5≦x≦2, 1.5≦y≦2 and 0.5≦s≦1 respectively, in order to ensure that variations in the direction of a magnetic field are not more than ±2° and that the magnetic field intensity is not less than 30 G.

For example, when x=1.5, y=1.5, z=0.5, in which case the size of the magnet assembly 7 becomes small, variations in the direction of a magnetic field were ±1.57° and the average magnetic field intensity was 47 G; and when x=2, y=2, z=1, in which case the size of the magnet assembly 7 becomes large, variations in the direction of a magnetic field were ±1.89° and the average magnetic field intensity was 31 G.

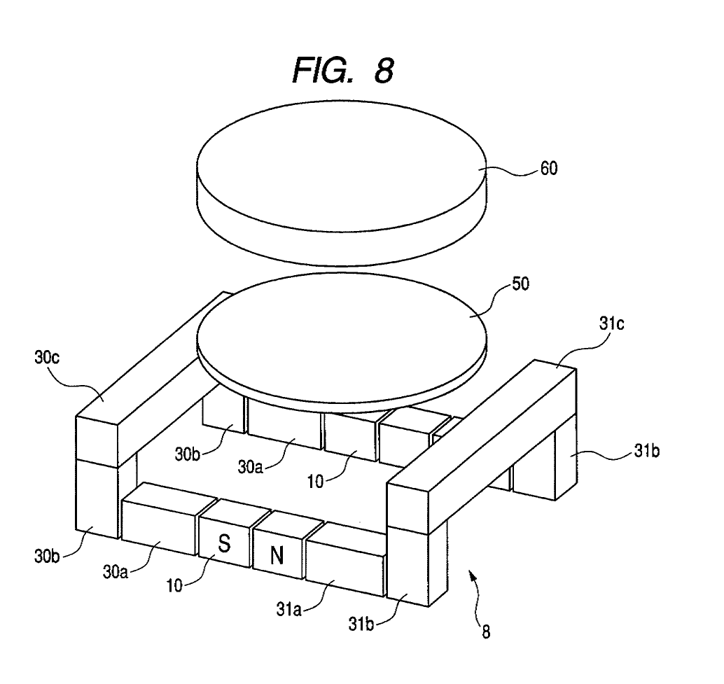

In the sputtering apparatus 8 of FIG. 6, the electrode that holds the target material may be configured to further include a cathode magnet 60 that rotates in synchronization with the rotation of the dipole magnet subassembly 10. The perspective view of this construction is shown in FIG. 8. In FIG. 8, a substrate holder 40 is omitted so that the construction of the magnet assembly 7 can be more clearly understood.

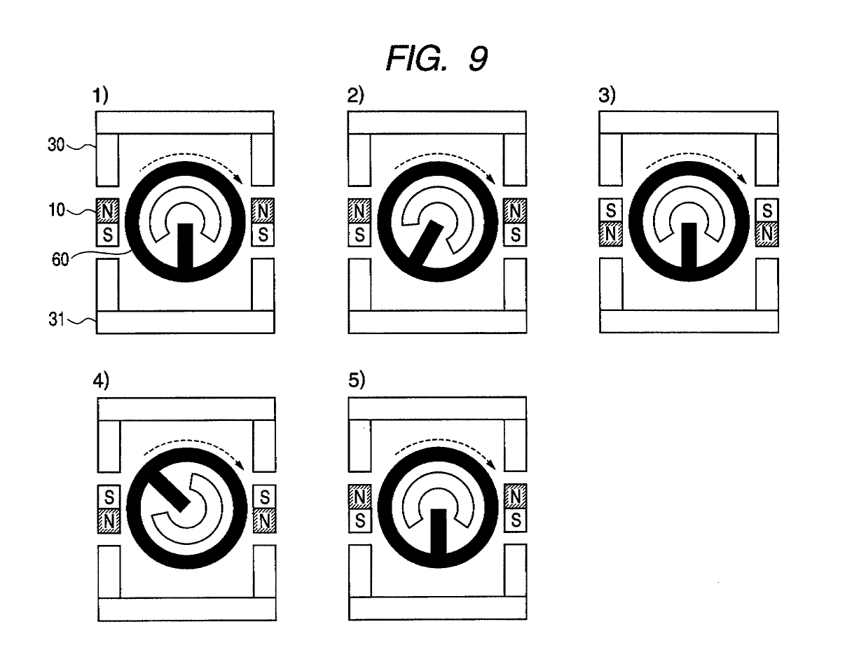

FIG. 9 is a view obtained by looking at the construction of FIG. 8 from above, and concretely shows the relationship between the rotation of the dipole magnet subassembly 10 and the rotation of the cathode magnet 60. The cathode magnet 60 is constantly rotating, and in the example of FIG. 9 the cathode magnet 60 is rotating clockwise as viewed from above. The cathode magnet 60 rotates from the position of 1) of FIG. 1, goes through the condition of 2) and the like, and comes to the same phase as in 1) again. Then, in synchronization with this timing, the rotation of the dipole magnet subassembly is reversed. The cathode magnet 60 continues to rotate further, goes through the condition of 4) and the like, and comes to the same phase as in 1) and 3) again at 5). The rotation of the dipole magnet subassembly 10 is reversed at this timing. In this manner, the dipole magnet subassembly 10 is synchronously controlled so that its rotation is reversed when the cathode magnet 60 that continues to rotating comes to a specific phase. The repeatability of the interference of a magnetic field by the dipole magnet subassembly 10 and the cathode magnet 60 is obtained and it becomes possible to obtain the repeatable uniform film thickness distributions.

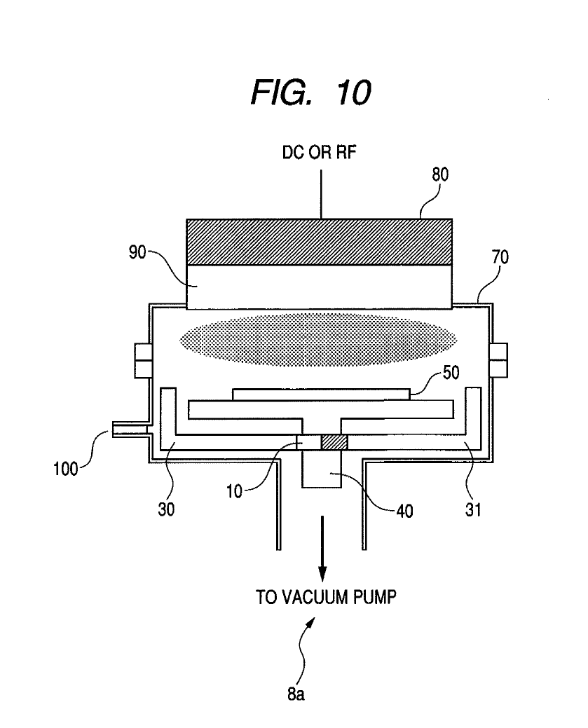

A more concrete example of the construction of the sputtering apparatus of this embodiment is shown in FIG. 10. In a sputtering apparatus 8a of FIG. 10, the structure shown in FIG. 5 is disposed within a vacuum chamber 70. Furthermore, an electrode 80 that holds a soft magnetic target 90 is disposed above a substrate 50, and DC or RF power is supplied to the electrode 80. When argon (Ar) gas or nitrogen (N₂) gas, for example, is introduced into the vacuum chamber 70 from a gas introduction port 100 and DC or RF power is applied to the electrode 80 that holds the target 90, a plasma is generated within the vacuum chamber 70. Ar ions and the like extracted from the plasma collide against the target 90 and a desired film is formed on the substrate 50 from sputtered particles from the target.

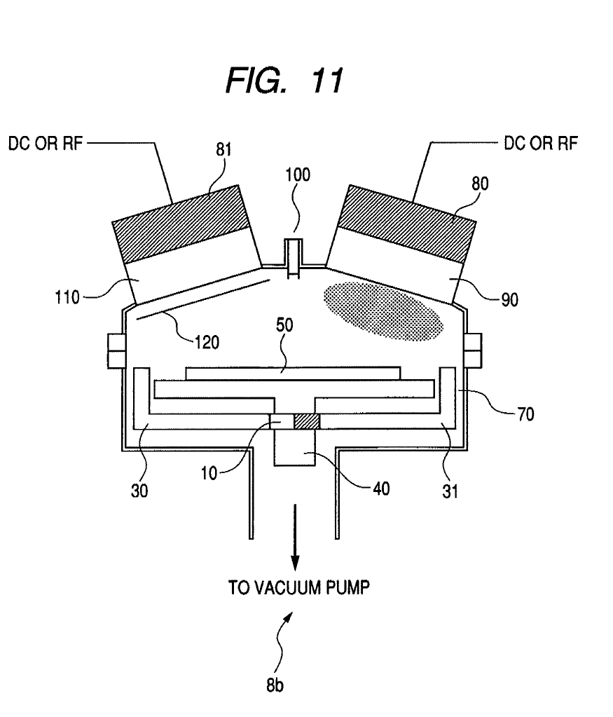

Another example of the construction of sputtering apparatus according to this embodiment is shown in FIG. 11. The sputtering apparatus 8b of FIG. 11 has a soft magnetic target 90 attached to an electrode 80 and a target 110 of an insulator (for example, MgO) attached to an electrode 81, and it is possible to form a stacked structure of a soft magnetic layer and an insulating layer on the substrate 50. The targets 90 and 110 are installed nonparallel to the surface of the substrate holder 40.

It is preferred that the diameter of the targets 90 and 110 be the same as or smaller than that of the substrate holder 40. DC power or RF power for generating a plasma is supplied to the electrodes 80 and 81. It is possible to introduce a working gas such as argon (Ar) and a reactive gas such as nitrogen (N₂) into the vacuum chamber 70 via a gas introduction port 100. A shutter 120, which can be opened only during film forming process and is closed except during firm forming process, is used to maintain film forming performance when a thin film is deposited. When DC power or RF power is applied to the electrodes 80, 81 that hold the targets 90, 110, a plasma is generated within the vacuum chamber 70. Ar ions and the like extracted from the plasma collide against the targets 90, 110 and a film of a soft magnetic layer or an insulating layer is formed from sputtered particles onto the substrate 50. Incidentally, as described above, the electrodes 80, 81 that support the targets 90, 110 may be configured to further include a cathode magnet 60 that rotates in synchronization with the rotation of the dipole magnet subassembly 10.

Although the present invention has been described for a few specific embodiments, the present invention is not limited thereto, and can be embodied by modifying (including deleting) various components in each of the embodiments so long as the modifications do not depart from the gist of the invention. It is also possible to form various inventions by replacing components among the various kinds of embodiments or combining a plurality of components of the various kinds of embodiments.

1. (canceled)

2. A magnet assembly comprising:
at least one rotatable dipole magnet subassembly, which is formed from a permanent magnet and two magnetically permeable convex end portions each coupled to the poles of the permanent magnet; and
at least two magnetically permeable flux guide subassemblies, which are configured so as to be magnetically coupled to the dipole magnet subassembly,
wherein each of the flux guide subassemblies has a concave end portion that fits into the convex end portion of the dipole magnet subassembly.
wherein when one of the convex end portions of the dipole magnet subassembly fits into the concave end portion of one of the flux guide subassemblies, the other convex end portion fits into the concave end portion of other flux guide subassembly and the flux guide assemblies guide a magnetic flux from the dipole magnet subassembly and generate a flux outside, and when the rotatable dipole magnet subassembly is rotated by 180 degrees. the direction of the magnetic field generated outside is reversed,
and wherein the magnet assembly comprises the dipole magnet subassembly Image Page 2 in quantities of at least two and the flux guide subassembly in quantities of at least three, and the at least two dipole magnet assemblies are disposed in tandem and at least one flux guide subassembly is disposed between the at least two dipole magnet assemblies.

3. The magnet assembly according to claim 2, wherein each of the flux guide subassemblies comprises a first arm having the concave end portion and a second arm that extends perpendicularly to the first arm from an end portion opposite to the concave end portion of the first arm, and a flux from the dipole magnet subassembly is guided by the first and second arms, whereby a magnetic field is generated outside an end of the second arm.

4. The magnet assembly according to claim 2, wherein the permanent magnet comprises a plurality of magnets having the same length.

5. The magnet assembly according to claim 2, wherein the permanent magnet comprises a plurality of magnets having different magnetic forces and a magnet of a stronger magnetic force is disposed nearer to the end portions of the permanent magnet.

6. The magnet assembly according to claim 2, wherein the flux guide subassemblies have a thickness that is not uniform.

7. The magnet assembly according to claim 2, wherein the magnet assembly has means for rotating the dipole magnetic assembly.

8. (canceled)

9. A sputtering apparatus that forms a thin film having a magnetic anisotropy of a uniform direction on a substrate, comprising:
a vacuum chamber;
a substrate holder disposed within the vacuum chamber; and
an electrode or source that holds a target material, and a magnet assembly, the magnet assembly comprising:
at least one rotatable dipole magnet subassembly, which is formed from a permanent magnet and two magnetically permeable convex end portions coupled to each of the poles of the permanent magnet; and
at least two magnetically permeable flux guide subassemblies, which are configured so as to be magnetically coupled to the dipole magnet subassembly,
wherein each of the flux guide subassemblies has a concave end portion that fits into the convex end portion of the dipole magnet subassembly,
wherein when one of the convex end portions of the dipole magnet subassembly fits into the concave end portion of one of the flux guide subassemblies, the other convex end portion fits into the concave end portion of other flux guide subassembly, and the flux guide assemblies guide a magnetic flux from the dipole magnet subassembly and generate a magnetic field on a surface of the substrate on the substrate holder,
wherein the condition of fitting into the at least two flux guide subassemblies is reversed by rotating the dipole magnet subassembly, whereby the direction of the magnetic field on the substrate surface is reversed,
and wherein the sputtering apparatus comprises the magnet assembly in quantities of two, and the two magnet assemblies are disposed in positions opposed to each other, with the substrate holder interposed therebetween.

10. A sputtering apparatus that forms a thin film having a magnetic anisotropy of a uniform direction on a substrate, comprising:
a vacuum chamber;
a substrate holder disposed within the vacuum chamber; and
an electrode or source that holds a target material, and a magnet assembly, the magnet assembly comprising:
at least one rotatable dipole magnet subassembly, which is formed from a permanent magnet and a magnetically permeable convex end portion coupled to each of both ends of the permanent magnet; and
at least two magnetically permeable flux guide subassemblies, which are configured so as to be magnetically coupled to the dipole magnet subassembly,
wherein each of the flux guide subassemblies has a concave end portion that fits into the convex end portion of the dipole magnet subassembly,
wherein when one of the convex end portions of the dipole magnet subassembly fits into the concave end portion of one of the flux guide subassemblies, the other convex end portion fits into the concave end portion of other flux guide subassembly and the flux guide assemblies guide a magnetic flux from the dipole magnet subassembly and generate a magnetic field on a surface of the substrate on the substrate holder,
wherein the condition of fitting into the at least two flux guide subassemblies is reversed by rotating the dipole magnet subassembly, whereby the direction of the magnetic field on the substrate surface is reversed,
and wherein each of the magnet assemblies comprises the dipole magnet subassembly in quantities of at least two and the flux guide subassembly in quantities of at least three, and the at least two dipole magnet assemblies are disposed in tandem and the at least one flux guide subassembly is disposed between the at least two dipole magnet assemblies.

11. (canceled)

12. A sputtering apparatus that forms a thin film having a magnetic anisotropy of a uniform direction on a substrate comprising:
a vacuum chamber:
a substrate holder disposed within the vacuum chamber; and
an electrode or source that holds a target material, and a magnet assembly, the magnet assembly comprising:
at least one rotatable dipole magnet subassembly, which is formed from a permanent magnet and a magnetically permeable convex end portion coupled to each of both ends of the permanent magnet: and
at least two magnetically permeable flux guide subassemblies, which are configured so as to be magnetically coupled to the dipole magnet subassembly,
wherein each of the flux guide subassemblies has a concave end portion that fits into the convex end portion of the dipole magnet subassembly,
wherein when one of the convex end portions of the dipole magnet subassembly fits into the concave end portion of one of the flux guide subassemblies, the other convex end portion fits into the concave end portion of other flux guide subassembly and the flux guide assemblies guide a flux from the dipole magnet subassembly and generate a magnetic field on a surface of the substrate on the substrate holder,
wherein the condition of fitting into the at least two flux guide subassemblies is reversed by rotating the dipole magnet subassembly, whereby the direction of the magnetic field on the substrate surface is reversed,
wherein each of the flux guide subassemblies comprises a first arm having the concave end portion and a second arm that extends perpendicularly to the first arm from an end portion opposite to the concave end portion of the first arm, and a magnetic flux from the dipole magnet subassembly is guided by the first and second arm,
and wherein the sputtering apparatus comprises the magnet subassembly in quantities of two, in that the two magnet assemblies are disposed in positions opposed to each other, with the substrate holder interposed therebetween, and the sputtering apparatus further comprises a third arm that connects each of the second arms of the opposed flux guide subassemblies.

13. The sputtering apparatus according to claim 9, wherein the permanent magnet comprises a plurality of magnets having the same length.

14. The sputtering apparatus according to claim 9, wherein the permanent magnet comprises a plurality of magnets having different magnetic forces and a magnet of a stronger magnetic force is disposed nearer to the end portions of the permanent magnet.

15. The sputtering apparatus according to claim 9, wherein the flux guide subassemblies have a thickness that is not uniform.

16. The sputtering apparatus according to claim 9, wherein the magnet assembly has means for rotating the dipole magnetic subassembly.

17. The sputtering apparatus according to claim 9, wherein the magnet assembly is disposed outside the vacuum chamber.

18. The sputtering apparatus according to claim 9, wherein the magnet assembly is disposed inside the vacuum chamber.

19. A sputtering apparatus that forms a thin film having a magnetic anisotropy of a uniform direction on a substrate comprising:
a vacuum chamber;
a substrate holder disposed within the vacuum chamber; and
an electrode or source that holds a target material, and a magnet assembly, the magnet assembly comprising:
at least one rotatable dipole magnet subassembly, which is formed from a permanent magnet and a magnetically permeable convex end portion coupled to each of both ends of the permanent magnet; and
at least two magnetically permeable flux guide subassemblies, which are configured so as to be magnetically coupled to the dipole magnet subassembly,
wherein each of the flux guide subassemblies has a concave end portion that fits into the convex end portion of the dipole magnet subassembly,
wherein when one of the convex end portions of the dipole magnet subassembly fits into the concave end portion of one of the flux guide subassemblies, the other convex end portion fits into the concave end portion of other flux guide subassembly and the flux guide assemblies guide a magnetic flux from the dipole magnet subassembly and generate a magnetic field on a surface of the substrate on the substrate holder.
wherein the condition of fitting into the at least two flux guide subassemblies is reversed by rotating the dipole magnet subassembly, whereby the direction of the magnetic field on the substrate surface is reversed.
wherein each of the flux guide subassemblies comprises a first arm having the concave end portion and a second arm that extends perpendicularly to the first arm from an end portion opposite to the concave end portion of the first arm, and a flux from the dipole magnet subassembly is guided by the first and second arm,
wherein the sputtering apparatus comprises the magnet assembly in quantities of two, in that the two magnet assemblies are disposed in positions opposed to each other, with the substrate holder interposed therebetween, and the sputtering apparatus further comprises a third arm that connects each of the second arms of the opposed flux guide subassemblies,
and wherein when the diameter of the substrate is denoted by D and the length L, width W and height H of the magnet assembly are represented by L=xD, W=yD and H=zD, respectively, the following relationships hold: 1.5≦x≦2, 1.5≦y≦2 and 0.5≦z≦1.

20. The sputtering apparatus according to claim 9, wherein the electrode further comprises a cathode magnet that rotates in synchronization with the rotation of the dipole magnet subassembly.
